(19) United States
(12) Patent Application Publication
(10) Pub. No.: US 2026/0214875 A1
(43) Pub. Date: Jul. 23, 2026

(54) ARTICLES FOR ELECTROMAGNETIC WAVE ATTENUATION

(71) Applicant: Henkel AG & Co. KGaA, Duesseldorf (DE)

(72) Inventor: Cheng Gu, Bloomington, MN (US)

(21) Appl. No.: 19/571,617

(22) Filed: Mar. 19, 2026

Related U.S. Application Data
(63) Continuation of application No. PCT/US2024/057990, filed on Nov. 29, 2024.
(60) Provisional application No. 63/603,687, filed on Nov. 29, 2023.

(51) Int. Cl. H05K 9/00

(52) U.S. Cl. CPC H05K 9/0088; H05K 9/0083

(57) ABSTRACT

An interface article for attenuating electromagnetic frequency radiation includes a multiple-layer construction with a first layer having a low index of refraction, and a second layer having a high index of refraction. The article includes ceramic fillers, metallic fillers, graphite fillers, or combinations thereof dispersed in a polymeric matrix. The interface article is tunable to exhibit at least 75% reduction of reflection of incident electromagnetic radiation at a target frequency of between 0.3-100 GHz.

### FIELD

The present invention relates to electromagnetic frequency attenuation materials and method of making the same, and particularly to materials effective to diminish reflection of electromagnetic frequencies between 0.3-100 GHz, which covers most 4G and 5G telecommunication applications.

### BACKGROUND

Mobile telecommunications systems employing 5G standards are currently using <6 GHz frequencies and between 8 and 24 radio frequency components in one radio unit in active multiple-input, multiple-output (MIMO) technology. It is anticipated that telecommunications installations will transition to higher frequencies (<40 G Hz) that use millimeter wave technology, which will require an increase in the number of radio frequency components from 16 to upwards of 1,024 or more in a single radio unit. The greatly increased component densities therefore presents a need to manage electromagnetic interference (EMI) generated to prevent unwanted signal interference. EMI disrupts the electromagnetic energy transmitted between electronic devices, and results in decreased performance or even failure of a circuit. Examples of deleterious effects caused by EMI are distorted or jammed signals between communication devices, power fluctuations and outage, electrical fast transitions (EFT), shock, and shortened shelf life. Devices sensitive to EMI include for example, cellular phones, laptop computers, servers, ECUs, ADAS sensors, inverters/converters, transceivers, RRUs and other high-power electronic devices. As of today, EMI shielding is the preferred solution to address these issues.

Most conventional EMI shielding solutions are based on highly electrically conductive materials that reflect almost all electromagnetic waves. Some solutions incorporate electromagnetic radiation-absorbing materials such as high permeability magnetic substances including magnetic metal powders, magnetic metal alloy powders, magnetic ceramics, high permittivity dielectric substance, and combinations thereof. The attenuation provided by these EMI shielding materials is derived from both absorption and reflection mechanisms. However, the permeability of magnetic substances significantly diminishes as frequencies increase to the GHz range, and dielectric materials behave much more like conductors at high frequencies. Therefore, in frequency ranges typically utilized by advanced telecommunication systems, magnetic EMI shielding materials become much less effective, and conventional magnetic, dielectric and conductive EMI shielding materials reflect up to 50% or more of the total electromagnetic energy, causing secondary pollution or resonance interference.

There is accordingly a need for an electromagnetic radiation attenuation apparatus with anti-reflective properties for high-frequency incident radiation. Combination apparatus having both anti-reflection and absorption properties may effectively suppress and even eliminate electromagnetic interference that is currently seen at high application frequencies. Anti-reflective structured interfaces have been widely used in optical lenses, solar power photovoltaic cells, microelectronic photolithography and other optical elements and near infrared applications. For radio and electromagnetic wave frequencies, however, the use of anti-reflective apparatus is less common, mainly because radio or electromagnetic wavelengths at the destructive interference frequencies are too long, typically a few meters to kilometers. Such arrangement would require anti-reflective apparatus of gigantic dimensions. As the telecommunications applications move towards higher frequencies (<40 GHz), the electromagnetic radiation wavelength in many materials is on the centimeter or millimeter scale. An effective anti-reflective interface with a thickness from a few millimeters to several hundred microns becomes practically feasible for electromagnetic radiation suppression in this regime. Therefore, the present invention relates to a highly effective radiation suppression apparatus for placement in proximity to the electromagnetic energy conversion device.

### SUMMARY

Apparatus for attenuating electromagnetic waves is described, comprising a cross-linked polymeric matrix filled with ceramic fillers, metallic fillers, graphite or combinations thereof. In typical embodiments, polymer composites of different refractive indices form a multiple-layer apparatus that absorbs millimeter to centimeter electromagnetic waves and suppresses reflection at or near a specific frequency within a given frequency range. The refractive index of the polymer composite in the first layer may be lower than that of the polymer composite in the second layer. The refractive index of the first layer is preferably proportional to the square root of the refractive index of the second layer. The second layer may include electromagnetic radiation suppression material and may accordingly function as electromagnetic radiation absorber.

In an exemplary embodiment, an article for attenuating electromagnetic radiation includes a first layer having a first thickness defined between an incident surface and a transition surface thereof, a first polymer matrix, and a first filler in the first polymer matrix. The first layer exhibits a first index of refraction to the electromagnetic radiation. The article further includes a second layer disposed at the transition surface of the first layer, wherein the second layer includes a second polymer matrix and a second filler in the second polymer matrix suitable to absorb at least a portion of the electromagnetic radiation propagating into the second layer. The second layer exhibits a second index of refraction to the electromagnetic radiation, wherein the first index of refraction is less than the second index of refraction by an amount that is effective to reduce emission reflection of the electromagnetic radiation incident upon the incident surface by at least 75%, and wherein the incident electromagnetic radiation frequency is between 0.3-100 GHz.

In some embodiments, the first thickness is between 0.1 mm and 20 mm, and may preferably be between 0.5 mm and 4 mm.

In some embodiments, the electromagnetic radiation exhibits a first wavelength in the first layer, and the first thickness is a product of the first wavelength and a destructive interference frequency factor that is between 0.2 and 0.3. In some embodiments, the destructive interference frequency factor is between 0.22 and 0.28.

In some embodiments, the first index of refraction is within 25% of a square root of the second index of refraction, and may be within 10% of a square root of the second index of refraction.

For electromagnetic frequencies of between 12-18 GHz, the first index of refraction may be between 1-7, and the second index of refraction may be between 5-16.

In some embodiments, the first filler may be selected from alumina, aluminum nitride, boron nitride, magnesia, alumina trihydrate, titanium dioxide, zinc oxide, aluminum hydroxide, zinc nitride, silicon carbide, silicon nitride, and combinations thereof.

In some embodiments, the second filler may be selected from silicon carbide, titanium dioxide, barium titanate, zinc oxide, aluminum powder, silver powder, magnetic metal powders, magnetic metal alloy powders, carbon fibers, graphite, carbon nanotubes, magnetic ceramics, iron, carbonyl ion, iron oxide, iron alloys, zinc alloys, and combinations thereof.

In some embodiments, the first polymer matrix and the second polymer matrix are selected from silicone, polyethylene, polybutadiene, acrylic, epoxy, urethane, polysulfide, polyisobutylene, polyvinyl or polyolefin-based polymers, and combinations thereof. The first polymer matrix may employ a different polymer or polymer combination that the second polymer matrix.

In some embodiments, the first polymer matrix comprises less than 10% by weight of the first layer.

Another exemplary embodiment includes an article for attenuating electromagnetic radiation, wherein the article includes a first layer having a first thickness defined between an incident surface and a transition surface. The first layer further includes a first polymer matrix, and a first filler in the first polymer matrix. The electromagnetic radiation exhibits a first wavelength in the first layer, wherein the first thickness is a product of the first wavelength and a destructive interference frequency factor of between 0.2 and 0.3, the first thickness being between 0.1 mm and 20 mm. The article further includes a second layer having a first surface disposed at the transition surface of the first layer, wherein the second layer includes a second polymer matrix.

In some embodiments, a second filler may be dispersed in the second polymer matrix suitable to absorb at least a portion of the electromagnetic radiation propagating into the second layer.

The second layer exhibits a second index of refraction, and the first layer exhibits a first index of refraction that is within 25% of a square root of the second index of refraction.

In some embodiments, a reflector member may be disposed at a second surface of the second layer, wherein the reflector member may be effective to reflect electromagnetic radiation propagating through the second layer from the first layer.

An electronic apparatus in accordance with the invention includes an electronic device that operably emits electromagnetic radiation in a frequency range of between 0.3-100 GHz. The apparatus further includes an attenuation article in proximity to the electronic device for attenuating the electromagnetic radiation.

In some embodiments, at least the first layer of the attenuation article exhibits a Young's Modulus of less than 1 MPa at 25° C. In some embodiments, each of the first and second layers of the attenuation article exhibits a Young's Modulus of less than 1 MPa at 25° C.

### BRIEF DESCRIPTION OF THE DRAWINGS

FIG. 1 is a cross-sectional view of an electromagnetic radiation attenuation article of the present invention;

FIG. 2 is a schematic illustration of a conventional electromagnetic interference shield;

FIG. 3 is a schematic illustration of an electromagnetic radiation attenuation article of the present invention;

FIG. 4 is a cross-sectional view of an electromagnetic radiation attenuation article of the present invention;

FIG. 5 is a cross-sectional view of an electromagnetic radiation attenuation article of the present invention;

FIG. 6 is a cross-sectional view of an electronic apparatus of the present invention;

FIG. 7 is a chart showing the influence of filler loading weight fraction on the refractive index of a silicon carbide-filled polymer composite;

FIG. 8 is a chart showing the influence of different filler systems on the refractive index of polymer composites;

FIG. 9 is a chart showing the influence of different filler systems on the electromagnetic wavelength in a filled polymer composite;

FIG. 10 is a chart showing return loss of radiation tested upon electromagnetic radiation attenuation articles of the present invention;

FIG. 11 is a chart showing reflection of radiation tested upon single-layer filled polymer composites;

FIG. 12 is a chart showing reflection of radiation tested upon electromagnetic radiation attenuation articles of the present invention;

FIG. 13 is a chart showing absorption of radiation tested upon single-layer filled polymer composites;

FIG. 14 is a chart showing absorption of radiation tested upon electromagnetic radiation attenuation articles of the present invention;

FIG. 15 is a chart showing reflection of radiation tested upon electromagnetic radiation attenuation articles of the present invention;

FIG. 16 is a chart showing absorption of radiation tested upon electromagnetic radiation attenuation articles of the present invention;

FIG. 17 is a chart showing reflection of radiation tested upon electromagnetic radiation attenuation articles of the present invention;

FIG. 18 is a chart showing absorption of radiation tested upon electromagnetic radiation attenuation articles of the present invention;

FIG. 19 is a chart showing reflection of radiation tested upon electromagnetic radiation attenuation articles of the present invention; and

FIG. 20 is a chart showing absorption of radiation tested upon electromagnetic radiation attenuation articles of the present invention.

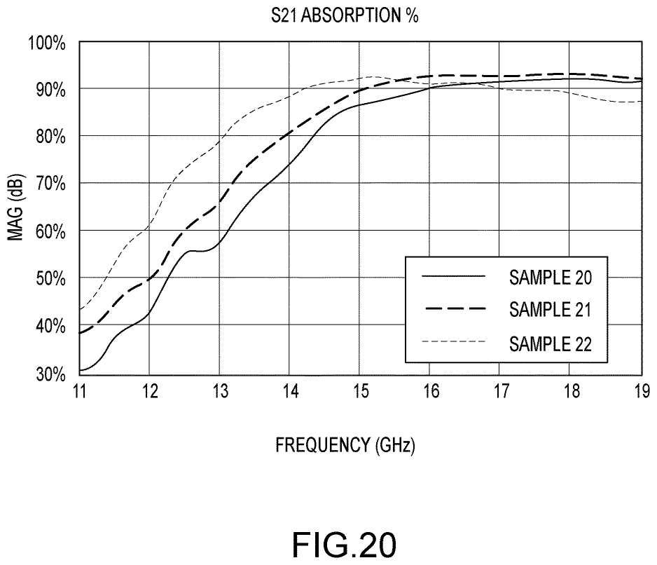

### DETAILED DESCRIPTION

The objects and features enumerated above together with other objects, features, and advances represented by the present invention will now be presented in terms of detailed embodiments described with reference to the drawing figures. Other aspects of the invention are recognized as being within the grasp of those having ordinary skill in the art.

Described herein is apparatus for suppression or elimination of electromagnetic wave reflection and a method of making the same. An example application frequency may be between 0.3-100 GHz, and preferably between 2.1-86 GHz, which ranges incorporate most 4G and 5G telecommunication application frequencies.

For the purposes hereof, the terms “electromagnetic radiation”, “electromagnetic interference” “electromagnetic wave” and “EMI”, are intended to mean radiation with millimeter or centimeter wavelengths (0.001-0.1 m) that is capable of interfering with the normal operation of electronic components, such as processors, transmitters, receivers, and the like. Such radiation may typically be in the range of 0.3-100 GHz, and preferably in the range of 2.1-86 GHz. The terms listed above, as well as other similar terms, are intended to refer to radiation in this frequency range and may therefore be used interchangeably to define the radiation transmission affected (absorbed, reflected, contained, etc.) by the materials of the present invention.

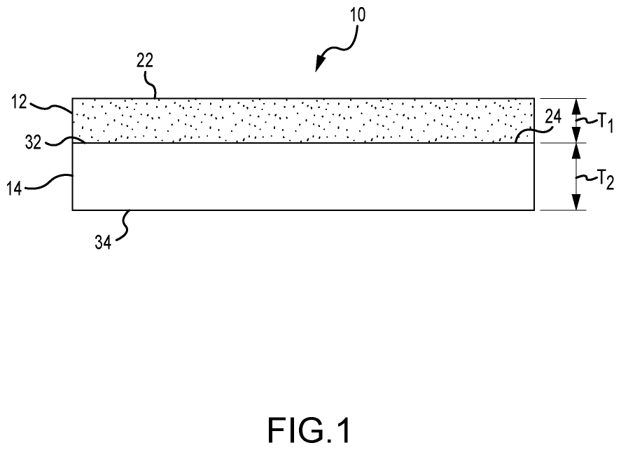

In an exemplary embodiment, an electromagnetic radiation attenuation apparatus for suppressing reflection of electromagnetic radiation includes a multiple-layer article having a low refractive index layer and a high refractive index layer. With reference to the drawing figures, FIG. 1 is a cross-sectional view of an article 10 of the present invention. Article 10 includes a first layer 12 and a second layer 14. First layer 12 has a first thickness “T₁” that is defined between an incident surface 22 and a transition surface 24. Second layer 14 includes a first surface 32 and a second surface 34. Second layer 14 may be disposed at transition surface 24 of first layer 12.

As described herein, article 10 is effective to attenuate electromagnetic radiation, and is particularly useful in attenuating electromagnetic radiation incident upon article 10 at incident surface 22 of first layer 12. The attenuation of electromagnetic radiation incident upon article 10 at incident surface 22 is facilitated by an anti-reflective effect that may be tuned to an electromagnetic frequency range of interest to suppress or eliminate emission reflection of the incident electromagnetic radiation.

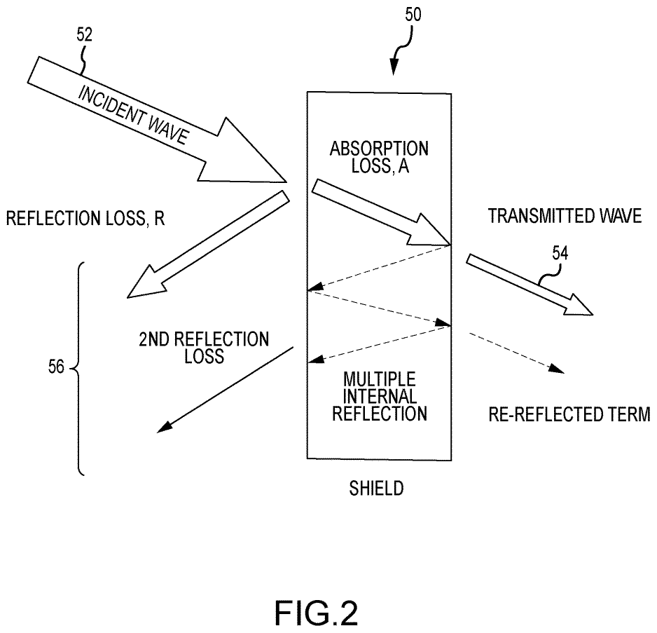

A conventional EMI shielding apparatus 50 is illustrated in FIG. 2, schematically showing shielding of an incident electromagnetic wave 52. Shielding apparatus 50 may be configured to absorb a portion of the incident electromagnetic radiation 52, demonstrated by the absorption loss “A”. Other portions of the incident electromagnetic radiation 52 may be re-directed due to reflection loss “R” and second reflection loss following internal reflection of the incident radiation 52, which together constitute an emission reflection 56. The transmitted wave 54, as well as re-reflected radiation, represents the extent of transmission electromagnetic radiation passing through shielding apparatus 50. Shielding effectiveness (SE) is represented by the following relationship:

$$SE = R + A + B$$

wherein B=a multiple reflection factor.

As described above, radiation attenuation apparatus as in the present invention seek to diminish emission reflection from the incident radiation, as well as transmission radiation through the apparatus, so as to maximize SE. Conventional EMI shielding apparatus demonstrates insufficient radiation attenuation, particularly at frequency ranges of between 0.3-100 GHz.

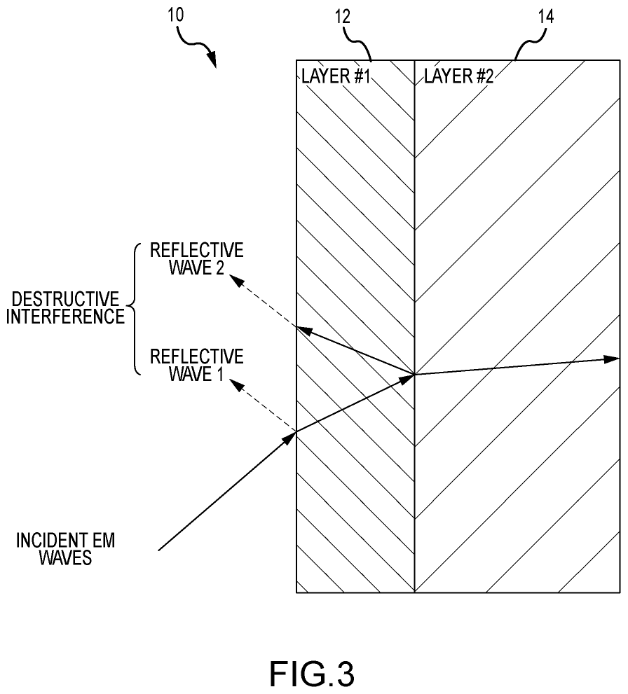

The attenuation effect provided by the present invention in the frequency range of interest is facilitated in part by suppression or elimination of reflection at the interface between the environmental media and the incident surface. FIG. 3 schematically illustrates article 10 of the present invention, in which electromagnetic radiation may be substantially attenuated by tuning the respective indices of refraction of first and second layers 12, 14 to the frequency of the incident radiation so that reflected radiation from incident surface 22 and transition surface 24 are out of phase and result in destructive interference with one another. The destructive interference among “Reflective wave 1” and “Reflective wave 2”, as illustrated in FIG. 3 may be controlled by relationships among the electromagnetic radiation wavelength (λ), the thickness (T₁) of first layer 12, and the relative refractive indices (n₁) of first layer 12 and (n₂) of second layer 14.

In some embodiments, the reflected radiation from incident surface 22 is out of phase from the reflected radiation from transition surface 24 to cause destructive interference of the two reflected electromagnetic waves. Destructive interference may be caused, at least in part, by constructing first layer 12 with a first thickness (T₁) in relation to the electromagnetic radiation wavelength (λ) in first layer 12. A destructive interference frequency factor (F) is determined by the following relationship:

$$F = {T}_{1} / λ$$

To maximize destructive interference effects, factor (F) is preferably within a specific range. In some embodiments, factor (F) is in a range of between 0.1 and 0.4. In some embodiments, factor (F) is in a range of between 0.2 and 0.3. In some embodiments, factor (F) is in a range of between 0.22 and 0.28. In some embodiments, factor (F) is about 0.25.

In this manner, article 10, and particularly first layer 12, may be configured with a first thickness T₁ that is proportional to the wavelength of the electromagnetic radiation in first layer 12. It is recognized, therefore, that article 10 of the present invention may be tuned in its dimensions to best achieve destructive interference of reflected waves, based upon the wavelength (λ) of the electromagnetic radiation in first layer 12. Such destructive interference promotes an anti-reflective property of article 10 of the present invention.

Applicant has found that, for incident electromagnetic radiation frequencies of between 0.3 and 100 GHz, first thickness T₁ may be between 0.1 and 20 mm. In some embodiments, first thickness T₁ may be between 0.1 and 10 mm. In some embodiments, first thickness T₁ may be at least 0.1, 0.2, 0.3, 0.4, or 0.5 mm, and no greater than 5, 6, 7, 8, 9, or 10 mm. In some embodiments, first thickness T₁ may be between 0.5 and 4 mm.

For incident electromagnetic radiation frequencies of between 0.3 and 100 GHz, second thickness T₂ of second layer 14 may, in some embodiments, be between 0.1 and 5 mm. In some embodiments, second thickness T₂ may be between 0.2 and 3 mm. In some embodiments, second thickness T₂ may be between 0.25 and 2 mm.

Destructive interference may be further optimized by providing the relative indices of refraction (n₁, n₂) of first and second layers 12, 14 within specified relationships. In some embodiments, a first index of refraction n₁ of first layer 12 is less than a second index of refraction n₂ of second layer 14. The presence of two layers with unequal indices of refraction facilitates an internal reflection characteristic at transition surface 24 that is out of phase with the incident radiation in first layer 12. The out of phase Reflective wave 2, as shown in FIG. 3, results in destructive interference to diminish total emission reflection 56.

In some embodiments, first index of refraction n₁ is less than second index of refraction n₂ by an amount effective to reduce emission reflection 56 by at least 75% for incident radiation 52 having a frequency of between 0.3-100 GHz. In some embodiments, first index of refraction n₁ is less than second index of refraction n₂ by an amount effective to reduce emission reflection 56 by at least 85% for incident radiation 52 having a frequency of between 0.3-100 GHz. In some embodiments, first index of refraction n₁ is less than second index of refraction n₂ by an amount effective to reduce emission reflection 56 by at least 90% for incident radiation 52 having a frequency of between 0.3-100 GHz. In some embodiments, first index of refraction n₁ is less than second index of refraction n₂ by an amount effective to reduce emission reflection 56 by at least 95% for incident radiation 52 having a frequency of between 0.3-100 GHz.

Applicant has determined that desirable relationship among the first and second indices of refraction (n₁, n₂) for optimal suppression of electromagnetic reflection may be established where first index of refraction n₁ approaches the square root of second index of refraction n₂. The relationship is represented by:

$${n}_{1} = \sqrt{{n}_{2}}$$

This relationship is particularly true where the environmental medium for incident radiation 52 is air, which has an index of refraction of 1.0. For the purposes hereof, the term “environmental medium” means the medium immediately adjacent to reflection surface 22 of first layer 12. For applications in which the environmental medium is not air, the optimal relationship among the indices of refraction is:

$${n}_{1} = \sqrt{{n}_{0} \times {n}_{2}}$$

wherein n₀=the index of refraction of the environmental medium

In some embodiments, first index of refraction n₁ is within 25% of a square root of second index of refraction n₂. In some embodiments, first index of refraction n₁ is within 10% of a square root of second index of refraction n₂. In some embodiments, first index of refraction n₁ is within 5% of a square root of second index of refraction n₂. In some embodiments, first index of refraction n₁ is between 1 and 7 for electromagnetic frequencies of between 12-18 GHz. In some embodiments, second index of refraction n₂ is between 5 and 16 for electromagnetic frequencies of between 12-18 GHz.

The indices of refraction for first and second layers 12, 14 may be controlled by their material make-up, including the polymer matrix material, the filler material, and the weight concentrations of each, including their relative concentrations. In this regard, the anti-reflective properties of first layer 12 may be tuned for maximum effect on the expected electromagnetic radiation exposure by setting thickness T₁ and first index of refraction n₁ appropriately, per the relationships and guidelines described herein. In other words, by varying the first refractive index n₁ (based on, e.g., filler material and filler concentration), and/or the first thickness T₁, an anti-reflective property of first layer 12 is customizable to match the target incident radiation frequency.

It is contemplated that a one or more of a variety of thermoplastic and thermosetting resins may be useful in the polymer matrices of first and second layers 12, 14. Example resins for each of first and second layers 12, 14 include silicone, acrylic, urethane, epoxy, polysulfide, polyisobutylene, polyvinyl or polyolefin-based polymers, and combinations thereof. In some embodiments, a first polymer matrix of first layer 12 is less than 60 wt. % of first layer 12. In some embodiments, first polymer matrix of first layer 12 is less than 50 wt. % of first layer 12. In some embodiments, first polymer matrix of first layer 12 is less than 40 wt. % of first layer 12. In some embodiments, first polymer matrix of first layer 12 is less than 30 wt. % of first layer 12. In some embodiments, first polymer matrix of first layer 12 is less than 20 wt. % of first layer 12. In some embodiments, first polymer matrix of first layer 12 is less than 10 wt. % of first layer 12. In some embodiments, first polymer matrix of first layer 12 is less than 5 wt. % of first layer 12. First polymer matrix may comprise one or more polymer resins.

Similarly, a second polymer matrix of second layer 14 may be less than 60 wt. % of second layer 14. In some embodiments, second polymer matrix of second layer 14 is less than 50 wt. % of second layer 14. In some embodiments, second polymer matrix of second layer 14 is less than 40 wt. % of second layer 14. In some embodiments, second polymer matrix of second layer 14 is less than 30 wt. % of second layer 14. In some embodiments, second polymer matrix of second layer 14 is less than 20 wt. % of second layer 14. In some embodiments, second polymer matrix of second layer 14 is less than 10 wt. % of second layer 14. In some embodiments, second polymer matrix of second layer 14 is less than 5 wt. % of second layer 14. The second polymer matrix may comprise one or more polymer resins. The second polymer matrix may employ one or more polymer resins that are different than those employed in first layer 12.

In some embodiments, first layer 12 may include filler materials that assist in tuning first layer 12 to desired index of refraction properties that are suitable for attenuating target electromagnetic radiation. Various filler materials may be employed as a first filler in first layer 12. In some embodiments, the first filler may be selected from alumina, aluminum nitride, boron nitride, magnesia, alumina trihydrate, titanium dioxide, zinc oxide, aluminum hydroxide, zinc nitride, silicon carbide, silicon nitride, and combinations thereof.

First filler may comprise, in some embodiments, at least 40 wt. % of first layer 12. In some embodiments, first filler may comprise at least 50 wt. % of first layer 12. In some embodiments, first filler may comprise at least 60 wt. % of first layer 12. In some embodiments, first filler may comprise at least 70 wt. % of first layer 12. In some embodiments, first filler may comprise at least 80 wt. % of first layer 12. In some embodiments, first filler may comprise at least 90 wt. % of first layer 12. In some embodiments, first filler may comprise at least 95 wt. % of first layer 12.

In some embodiments, second layer 14 may include filler materials that assist in tuning second layer 14 to desired index of refraction properties that are suitable for attenuating target electromagnetic radiation. In some embodiments, the second filler material may be suitable for obtaining a second index of refraction that is higher than the first index of refraction. In some embodiments, the second filler may be selected from filler materials of higher refractive index than that of the filler materials in first layer 12. Suitable filler materials include silicon carbide, boron carbide, titanium dioxide, barium titanate, zinc oxide, aluminum powder, silver powder, magnetic metal powders, magnetic metal alloy powders, carbon fibers, graphite, carbon nanotubes, magnetic ceramics, iron, carbonyl ion, iron oxide, iron alloys, zinc alloys, and combinations thereof.

In some embodiments, second layer 14 may include one or more electromagnetic radiation suppression filler materials that are effective in absorbing electromagnetic radiation. Examples of such filler materials include silicon carbide, boron carbide, titanium dioxide, barium titanate, zinc oxide, aluminum powder, silver powder, magnetic metal powders, magnetic metal alloy powders, carbon fibers, graphite, carbon nanotubes, magnetic ceramics, iron, carbonyl ion, iron oxide, iron alloys, zinc alloys, and combinations thereof. The above filler materials are exemplary only, and are not intended to be limited to the use of various anti-reflective and EMI interference suppression materials known in the art. Filler materials in both the first and second layers 12, 14 may be dispersed in the respective polymeric matrix.

Second filler may comprise, in some embodiments, at least 40 wt. % of second layer 14. In some embodiments, second filler may comprise at least 50 wt. % of second layer 14. In some embodiments, second filler may comprise at least 60 wt. % of second layer 14. In some embodiments, second filler may comprise at least 70 wt. % of second layer 14. In some embodiments, second filler may comprise at least 80 wt. % of second layer 14. In some embodiments, second filler may comprise at least 90 wt. % of second layer 14. In some embodiments, second filler may comprise at least 95 wt. % of second layer 14.

The highly filled polymer composites of first and second layers 12, 14 may include a filler package containing different types of fillers, or the same filler of different particles sizes, or a combination thereof. In some embodiments, the filler package may include a multi-modal blend of particles with mean particle sizes (d₅₀) of 100-500 microns in a first mode, 1-100 microns in a second mode, and sub-micron sizes in a third mode. Highly filled polymer composites provide exceptional flexibility for tuning the refractive index and electromagnetic wavelength by adjust the filler types and weight fractions, and allow versatile combinations of fillers for multi-functional material design in, for example, thermal management plus EMI shielding. As the polymer matrix may account for a minority, or even a very small fraction of the total composition, the refractive index of the polymer composite becomes closer to the refractive index of the filler materials themselves. The filler materials in each of the first and second layers may be in the form of particulates, flakes, powders, filaments, fibers, or combinations thereof.

Conventional EMI suppression materials for electromagnetic or optical frequencies, and particularly materials useful as anti-reflective bodies tend to be relatively rigid. The electromagnetic radiation attenuation articles of the present invention possess good compliance due to the resin part in the composition. The conformability property is particularly useful in applications as an interface in electronic apparatus, such in thermal management applications between a radiation emitter and a heat sink. Good conformability allows better wetting and contact of materials at the interface and reduces air gaps and thermal barriers.

In some embodiments, at least first layer 12 of article 10 may exhibit a Young's modulus of less than 1 MPa, in some embodiments less than 0.5 MPa, and in some embodiments less than 0.2 MPa at 25° C. In some embodiments, each of first and second layers 12, 14 exhibit a Young's modulus of less than 1 MPa, in some embodiments less than 0.5 MPa, and in some embodiments less than 0.2 MPa at 25° C.

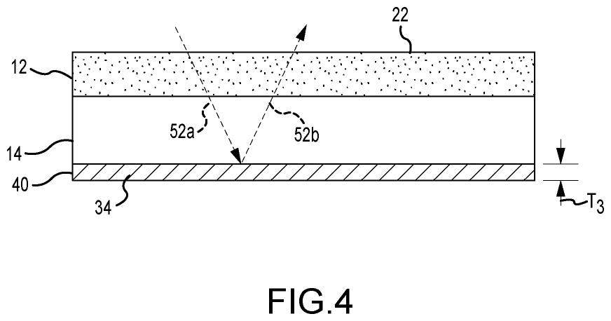

As illustrated in FIG. 4, article 10 may further include a reflector member 40 for reflecting electromagnetic radiation incident upon incidence surface 22 that is not attenuated by either destructive interference or absorption in first and second layers 12, 14. Reflector member 40 may therefore be disposed at, for example, second surface 34 of second layer 14. FIG. 4 schematically illustrates incident radiation 52a being reflected by reflector member 40 as reflection radiation 52b. Such reflection effectively doubles the absorption distance of article 10 through which the radiation must pass before exiting article 10, and therefore enhances the overall radiation attenuation properties of article 10. Reflector member 40 is preferably highly electrically conductive to substantially block electromagnetic radiation waves from passing therethrough as transmitted wave 54. Reflector member may form a continuous or discontinuous plate, sheet, foil, fabric, mesh, or combination structure that is effective in reflecting electromagnetic radiation, at least in a range of between 0.3 and 100 GHz. Example materials useful in reflector member 40 include aluminum foil, aluminum mesh, copper mesh, nickel coated copper taffeta fabric, stainless steel, metal filled polymer composites, carbon coated aluminum foil, carbon filled polymer composites, graphite sheets, and other metallic, carbon-based, or intrinsically conducting polymers (ICPs) such as Poly(3,4-ethylenedioxythiophene) (PEDOT), poly(p-phenylene sulfide) (PPS), polyacetylene (PAC), polyaniline (PANI), polypyrrole (PPY), polythiophene (PTH) based materials, poly(p-phenylene vinylene) (PPV), and combinations thereof.

In some embodiments, reflector member 40 may have a thickness (T₃) of between 1 micron and 1 mm. In some embodiments, reflector member 40 may have a thickness T₃ of between 5-500 μm. In some embodiments, reflector member 40 may have a thickness T₃ of between 10-200 μm.

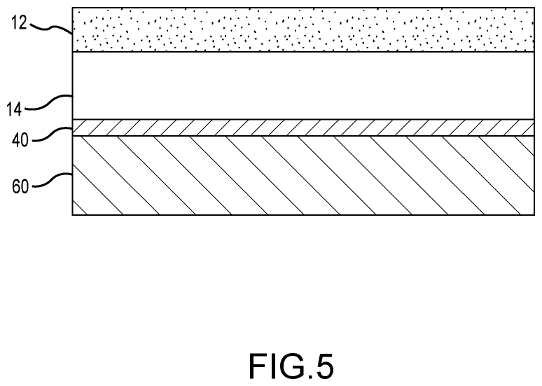

As illustrated in FIG. 5, article 10 may further include a function layer 60 for adding one or more properties to article 10. Functional layer 60 may be one or more of thermally conductive, tacky, low modulus, electrically insulative, mechanically reinforcing, and the like.

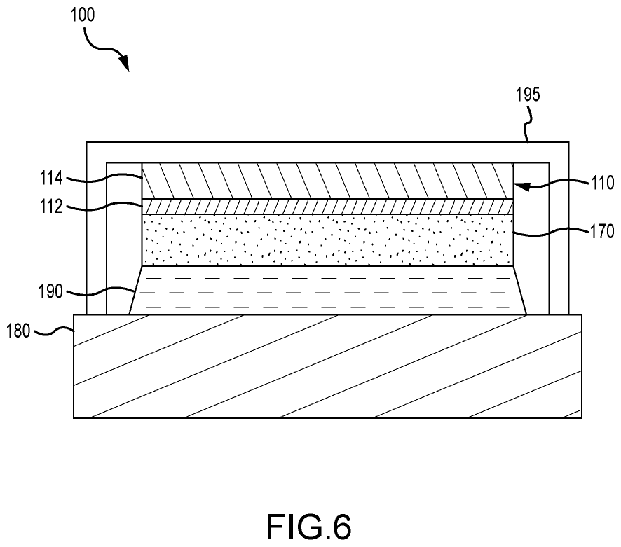

An electronic apparatus 100 of the present invention includes an electronic device 170 that operably emits electromagnetic radiation. In some embodiments, electronic device may operably emit electromagnetic radiation in a frequency range of between 0.3-100 GHz. In some embodiments, electronic device 170 may be a transmitter, a processor, an antenna, and the like. Electronic apparatus 100 illustrated in FIG. 6 includes a substrate 180, an underfill layer 190 to secure electronic device 170 to substrate 180, and an attenuation article 110 including a first layer 112 and a second layer 114, with first layer 112 positioned in proximity to electronic device 170 for attenuating the electromagnetic radiation. In some embodiments, a thermal dissipater and/or EMI shield member 195 may be secured to attenuation article 110 and substrate 180 to provide further beneficial properties to electronic device 170.

### EXAMPLES

The following examples set forth materials and methods for constructing example embodiments of the electromagnetic radiation attenuation articles of the present invention. The examples described herein, however, should not be considered limiting in any way as to the materials, construction, or methods of construction of the articles of the present invention.

### Example 1

A first, anti-reflective layer included the following composition:

| Ingredient | Description | Wt % | Source |
|---|---|---|---|
| Andisil Vinyl | Silicone Resin | 32.6 | AB Specialty Silicones |
| Silicone | | | |
| Andisil Hydride | Silicone Resin | 7.5 | AB Specialty Silicones |
| Silicone | | | |
| BYK-LP | Dispersing Agent | 1.4 | BYK |
| Cat 50 | Pt Catalyst | <0.1 | NuSil Technology LLC |
| BBN-5 | Boron Nitride | 2.3 | Ya'an Bestry Performance |
| | | | Materials Co., Ltd. |
| Polartherm | Boron Nitride | 32.9 | Momentive |
| PT 110A | | | |
| SP12 BN | Boron Nitride | 4.7 | Saint-Gobain |
| 800nm BN | Boron Nitride | 9.3 | US Research |
| | | | Nanomaterials, Inc. |
| AO-502 | Alumina | 9.3 | Admatechs |

The first layer was prepared by placing filler material and silicone resin into a container. The silicone resin includes silicone polymers containing a vinyl functional group, a hydride functional group, and a dispersing agent. The materials were then placed in a speed mixer for mixing at 800 rpm for 15 seconds under vacuum, and then 1200 rpm for 90 seconds under vacuum. After cooling to room temperature, a catalyst and inhibitor were added, and the sample mixed in a speed mixer at 800 rpm for 15 seconds, and then 1000 rpm for 60 seconds. The mixed sample was then poured onto an 80 mil thick rectangular stainless steel mold. Typically, FEP liners are placed between the sample and the surface of mold allowing easy release of the cured sample from the mold. The top plate was placed on the mold, and then manually pressed to flatten the sample in the mold. The mold and sample were then placed in a hot-press at 5 ton-force/square inch pressure at 120° C. for 60 minutes. After removing the mold from the hot press, the cured sample was released from the mold.

A second, absorption layer included the following composition:

| Ingredient | Description | Wt % | Source |
|---|---|---|---|
| Andisil Vinyl | Silicone Resin | 16.0 | AB Specialty Silicones |
| Silicone | | | |
| Andisil Hydride | Silicone Resin | 3.6 | AB Specialty Silicones |
| Silicone | | | |
| BYK-LP | Dispersing Agent | 0.6 | BYK |
| Cat 50 | Pt Catalyst | <0.1 | NuSil Technology LLC |
| Carborex | Silicon Carbide | 47.9 | Washington Mills |
| Green 180 | | | |
| Carborex | Silicon Carbide | 16.0 | Washington Mills |
| Green 7 | | | |
| BAK 1 | Alumina | 8.0 | Ya'an Bestry Performance |
| | | | Materials Co., Ltd. |
| Aerosil R974 | Fumed Silica | 8.0 | Evonik |

The second layer was prepared using the identical method as described in the preparation procedure for the first layer. The 1 mm fully cured first layer was placed onto a 120 mil thick rectangular mold, and the composition for the second layer was then poured onto the first layer with FIP liners disposed between the surface of the mold and the first layer. The top plate was placed on the mold and then gently pressed to flatten the sample in the mold, and placed in a hot-press at 5 ton-force/square inch pressure at 120° C. for 60 minutes. The mold was taken out of the hot press, and the cured sample released from the mold. The second layer typically firmly attaches to the first layer when silicone resins are used for making both layers. It is also feasible to make a 1 mm second layer first, followed by adding the first layer onto it.

### Testing

Electromagnetic reflection, absorption, permittivity and permeability measurements were conducted using a Vector Network Analyzer (VNA) according to the standard testing method ASTM D5568. VNA measures electrical network parameters (S parameters) including S11, S12, S21 and S22. Absorption and reflection are calculated from S parameters:

$$\% Reflection = 100 \% \times 1 {0}^{( \frac{S 11}{10} )}$$

$$\% Absorption = 100 \% \times ( 1 - {10}^{( \frac{S 11}{10} )} - {10}^{( \frac{S 21}{10} )} )$$

The refractive index and wavelength of a composite polymer material may be determined using a Vector Network Analyzer (VNA) testing apparatus. A coaxial fixture for the waveguide size of interest is selected, and a test specimen of appropriate dimension may be taken with a steel rule die that matches the waveguide size. The test specimen is then inserted and pressed into the waveguide fixture to an extent that ensures that the test specimen is in contact with all the interior surface of the fixture. The waveguide fixture is then mounted on the testing equipment, and a calibration may be performed at the frequency range corresponding to the selected waveguide size (e.g., X-band 8.2-12.4 GHz, Ku-band 12.4-18.0 GHz). The VNA test apparatus measures electrical network parameters (S parameters) including S11, S12, S21 and S22.

$${S}_{11} = \frac{Γ ( 1 - {T}^{2} )}{( 1 - {Γ}^{2} {T}^{2} )}$$

$${S}_{21} = \frac{T ( 1 - {Γ}^{2} )}{( 1 - {Γ}^{2} {T}^{2} )}$$

Where Γ is reflection coefficient, and T is transmission Coefficient. Permeability μᵣ and Permittivity εᵣ are calculated from S parameters using Nicolson-Ross-Weir Conversion method as follows:

$${μ}_{r} = \frac{1 - {Γ}_{1}}{Λ ( 1 - Γ ) \sqrt{\frac{1}{{λ}_{0}^{2}} - \frac{1}{{λ}_{c}^{2}}}}$$

$${ε}_{r} = \frac{{λ}_{0}^{2}}{{μ}_{r}} ( \frac{1}{{λ}_{c}^{2}} - {[ \frac{1}{2 π L} ln ( \frac{1}{T} ) ]}^{2} )$$

Where λ₀ is free space wavelength and λ_{c} is the cutoff wavelength. The refractive index n and wavelength λ of the material at a specific frequency is then calculated as follows:

$$n = \frac{c}{v} = \sqrt{{μ}_{r} {ε}_{r}}$$

$$λ = \frac{c}{nf} = \frac{c}{f \sqrt{{μ}_{r} {ε}_{r}}}$$

Where c is the speed of light in free space, and f is the frequency of interest.

All samples were measured using X-band 8.2-12.4 GHz, and Ku-band 12.4-18.0 GHz rectangular waveguide sections. Post-processing TRL calibration was used with a 12-term error model that corrects for reflections and crosstalk associated with a two-port system. The samples were cut using steel rule die to fit within each waveguide sample holder. The samples were tested for both radiation return loss (R_{L}) and insertion loss (I_{L}), measured in dB. Multiple samples of a same composition were measured, and the results were averaged together. The return loss of a material is directly related to the measured reflection coefficient (T) as follows:

$${R}_{L} = 20 {log}_{10} ( Γ )$$

The insertion loss is determined in a similar method using the measured transmission coefficient. The measured reflection coefficient is comprised of reflections from both faces of the sample. In general, as the return loss gets closer to zero dB, more energy is being reflected.

Shielding effectiveness (SE) is well known in the art for determining the effectiveness of materials in shielding electromagnetic radiation. The SE is derived from:

$$SE = S {E}_{R} + S {E}_{A} + S {E}_{B} = - 20 log {T}_{i} / {I}_{o}$$

Wherein, SE is total shielding effectiveness, SE_{R} is the electromagnetic energy loss due to reflection, SE_{A} is the electromagnetic energy loss due to absorption, and SE_{B} is the electromagnetic energy loss due to multiple reflection. SE_{B} is usually negligible compared to the magnitude of SE_{R} and SE_{A}. Tᵢ is transmitted radiation, Iₒ=incident radiation. SE_{A} (dB) and SE_{B} (dB) can be calculated from S parameters:

$$S {E}_{R} = - 10 log ( 1 - R ) and R = {\vert {S}_{11} \vert}^{2}$$

$$S {E}_{A} = - 10 log ( \frac{T}{1 - R} ) and T = {\vert {S}_{21} \vert}^{2}$$

And the reflection and absorption of electromagnetic radiation can be calculated as follows:

$$\% Reflection = 100 \% \times 1 {0}^{( \frac{S 11}{10} )}$$

$$\% Absorption = 100 \% \times ( 1 - {10}^{( \frac{S 11}{10} )} - {10}^{( \frac{S 21}{10} )} )$$

The influence of filler loading wt. % on refractive index (n) of the cured polymer composites, and the influence of different filler materials on refractive index (n) of the cured polymer composites is set forth in the Table below.

| | | | | | | Wave- |
|---|---|---|---|---|---|---|
| | | | | | Refractive | length |
| Sample | Matrix | Resin, | Main | Filler, | Index n @ | λ, mm @ |
| No. | Resin | wt % | Filler | wt % | 15 GHz | 15 GHz |
| 1 | Silicone | 51.0 | Silicon | 49.0 | 2.72 | 7.35 |
| | | | Carbide | | | |
| 2 | Silicone | 34.4 | Silicon | 65.6 | 3.26 | 6.14 |
| | | | Carbide | | | |
| 3 | Silicone | 20.2 | Silicon | 79.8 | 4.38 | 4.57 |
| | | | Carbide | | | |
| 4 | Silicone | 7.2 | Silicon | 92.8 | 6.79 | 2.94 |
| | | | Carbide | | | |
| 5 | Silicone | 6.3 | Silicon | 93.7 | 7.37 | 2.72 |
| | | | Carbide | | | |
| 6 | Silicone | 4.1 | Silicon | 95.9 | 8.04 | 2.49 |
| | | | Carbide | | | |
| 7 | Silicone | 3.2 | Alumina | 96.8 | 2.93 | 6.82 |
| 8 | Silicone | 4.8 | Aluminum | 95.2 | 2.63 | 7.60 |
| | | | Nitride | | | |
| 9 | Silicone | 10.1 | Magnesia | 89.9 | 2.46 | 8.14 |
| 10 | Silicone | 41.5 | Boron | 58.5 | 1.93 | 10.35 |
| | | | Nitride | | | |
| 11 | Silicone | 12.0 | MnZn | 88.0 | 5.48 | 3.65 |
| | | | Ferrite | | | |

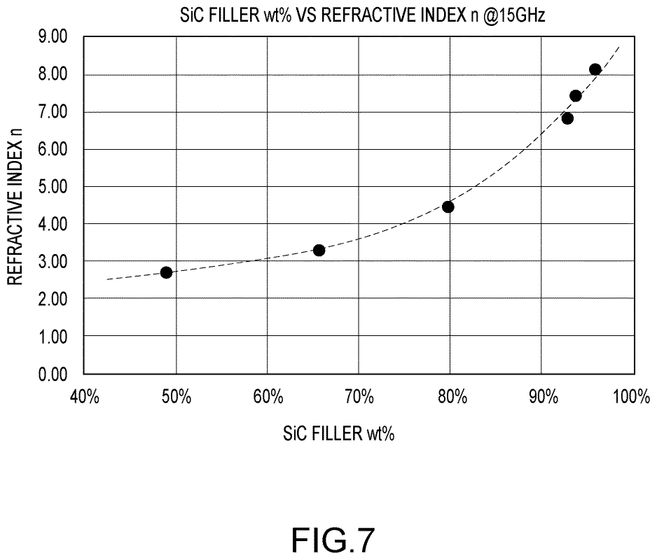

FIG. 6 shows the influence of filler loading weight fraction on the refractive index of silicon carbide based cured polymer composites, with the samples shown on the figure being listed in Table 3, Samples 1-6. Silicon carbide has higher refractive index than silicone resin in testing frequency range. With increasing weight fraction of silicone carbide fillers, the polymer composite demonstrates significant increased refractive index at a frequency of 15 GHz. Also shown in FIG. 7 shows the influence of filler materials on the refractive index of the polymer composites over frequencies of 12-18 GHz, with Samples 3 and 7-11 from Table 3 being represented in FIG. 7.

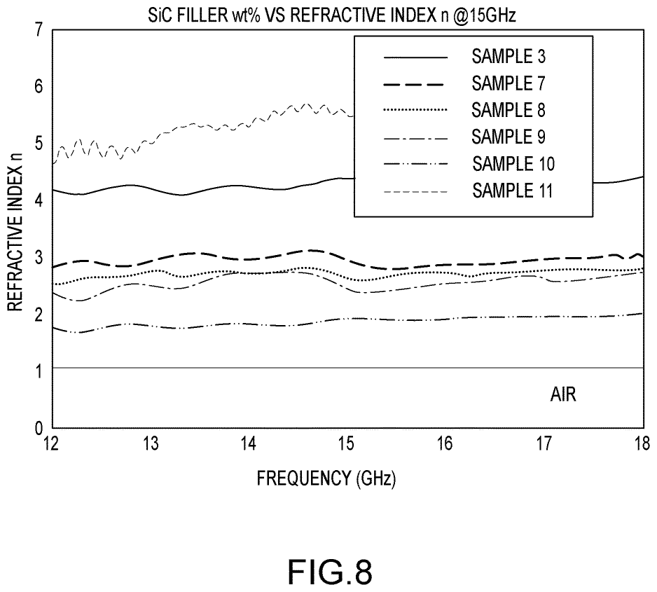

FIG. 8 shows the influence of filler materials on the wavelength of incident radiation in the layer over frequencies of 12-18 GHz, with Samples 3 and 7-11 from Table 3 being represented in FIG. 8. Applicant has found that, by adjusting the composition of the filler package, a wide range of refractive indices, for example 1.0-12.0, and a wide range of wavelengths, for example 0.2-3 mm, can be achieved using the same resin system in the frequency range of 12-18 GHz. For the purposes hereof, the term “main filler” in Table 3 means the predominant filler used in the composition. The main filler typically accounts for 70%, 80%, or 90% by weight fraction of the total fillers used in a polymer composite. Any of the present samples do not necessarily contain 100% of the same type of fillers.

The Table below sets forth the influence of thickness of the first layer on destructive interference frequency (f) for the cured polymer composite, when used in combination with the second layer, shown in the subsequent Table.

| | First Layer | | | | | |
|---|---|---|---|---|---|---|
| | | | | | | Destructive |
| | | | | | Thick- | Interference |
| Sample | Matrix | Resin, | Main | Filler, | ness, | Frequency |
| No. | Resin | wt % | Filler | wt % | mm | f, GHz |
| 12 | Silicone | 3.3 | Alumina | 96.7 | 1.25 | 17.1 |
| 13 | Silicone | 3.3 | Alumina | 96.7 | 1.50 | 15.9 |
| 14 | Silicone | 3.3 | Alumina | 96.7 | 1.75 | 15.0 |
| 15 | Silicone | 3.3 | Alumina | 96.7 | 2.00 | 12.4 |
| 16 | Silicone | 5.5 | Magnesia | 94.5 | 1.75 | 17.9 |
| 17 | Silicone | 5.5 | Magnesia | 94.5 | 2.00 | 14.3 |
| 18 | Silicone | 39.2 | Boron | 60.8 | 2.50 | 16.0 |
| | | | Nitride | | | |
| 19 | Silicone | 39.2 | Boron | 60.8 | 3.00 | 13.9 |
| | | | Nitride | | | |
| 20 | Silicone | 5.2 | Aluminum | 94.8 | 1.50 | 16.9 |
| | | | Nitride | | | |
| 21 | Silicone | 5.2 | Aluminum | 94.8 | 1.75 | 16.0 |
| | | | Nitride | | | |
| 22 | Silicone | 5.2 | Aluminum | 94.8 | 1.75 | 15.0 |
| | | | Nitride | | | |

The Table below sets forth the composition and thickness of the second layer used in connection with the first layers, shown in the prior Table.

| | Second Layer | | | | |
|---|---|---|---|---|---|
| | Matrix | Resin, | Main | Filler, | Thickness, |
| Sample No. | Resin | wt % | Filler | wt % | mm |
| For Samples | Silicone | 5.1 | Silicon | 94.9 | 1.00 |
| 12-22 | | | Carbide | | |

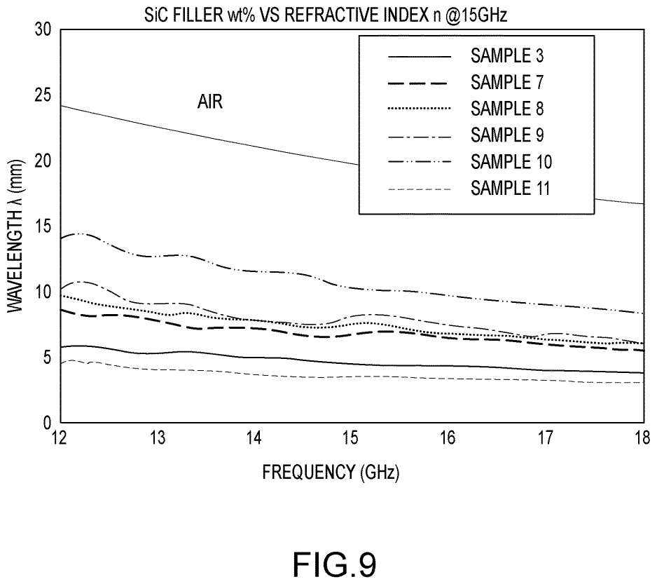

FIG. 9 shows the return loss (R_{L}) in dB of electromagnetic radiation tested upon electromagnetic radiation attenuation apparatus containing an alumina-based first layer polymer composite with a thickness of 1.25 mm, 1.50 mm, 1.75 mm, 2.00 mm (Samples 12-15), and a silicon carbide-based second layer polymer composite with a constant thickness of 1 mm, at a frequency range of 11-19 GHz. Both layers contain silicone polymeric matrix. The silicon carbide polymer composite second layer also functions as a dielectric electromagnetic absorber for pure experimental purposes, however the second layer by no means needs to have electromagnetic suppression properties. As shown in FIG. 9, the large dip in the R_{L} corresponds to the destructive interference frequency of each sample. With increasing thickness of the first layer, the wavelength of electromagnetic radiation needs to increase as well so that approximately one-fourth of the wavelength (¼λ) is equal to the thickness of the first layer. The magnitude differences in the return loss may contain an artifact that results from imperfect sample preparation, placement and distortion in the testing fixture.

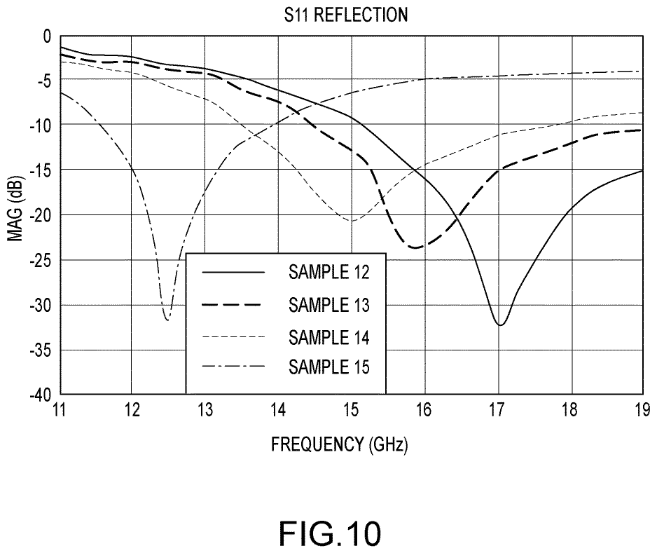

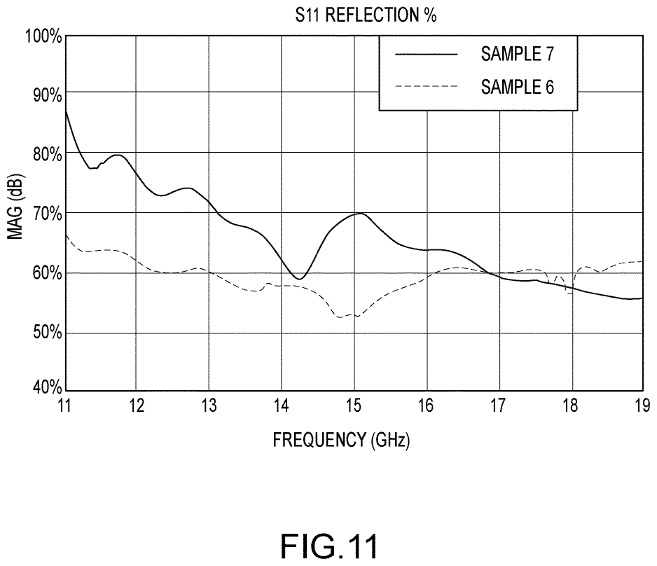

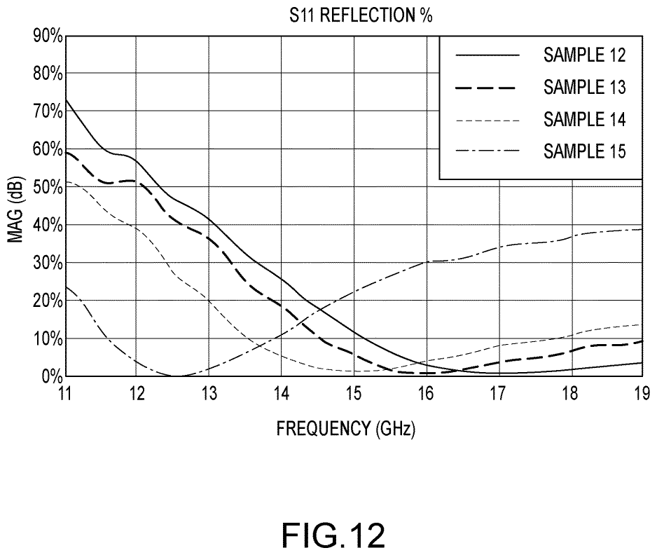

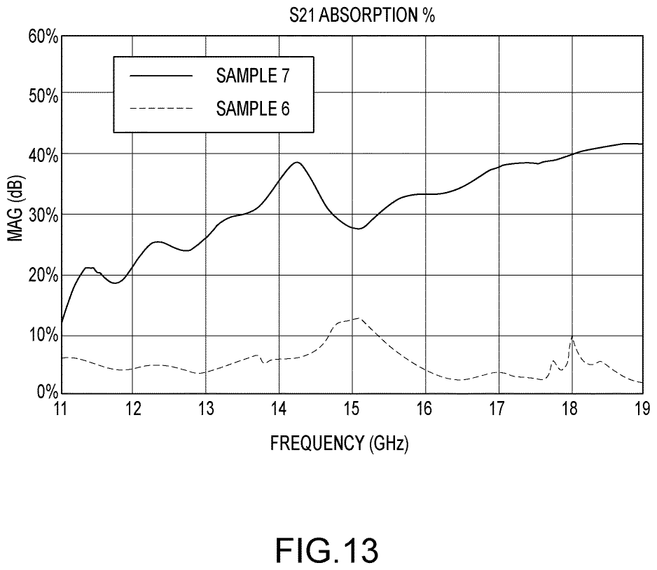

FIG. 10 shows S11 reflection data on single-layer apparatus using Samples 6 and 7 alone, and FIG. 11 shows S11 reflection data on electromagnetic attenuation apparatus containing dual layers of Samples 12-15 as the first layer, and the second layer as in Table 5. As demonstrated by comparing FIGS. 10 and 11, reflection decreased from about 60-70% to nearly 0% when employing the apparatus of the present invention. Absorption results are similar, as demonstrated in a comparison of FIGS. 12 and 13, wherein absorption increased from a maximum of about 40% when using the single-layer apparatus to approximately 90% in the multiple-layer apparatus of the present invention.

It can be seen in these exemplary embodiments, the articles of the present invention exhibit at least 75%, 85%, or 95% reduction of reflection of an incident electromagnetic radiation at a destructive interference frequencies, and in some embodiments, the articles of the present invention exhibit at least 98.0%, 98.5%, 99.0%, 99.5% reduction of reflection at destructive interference frequencies.

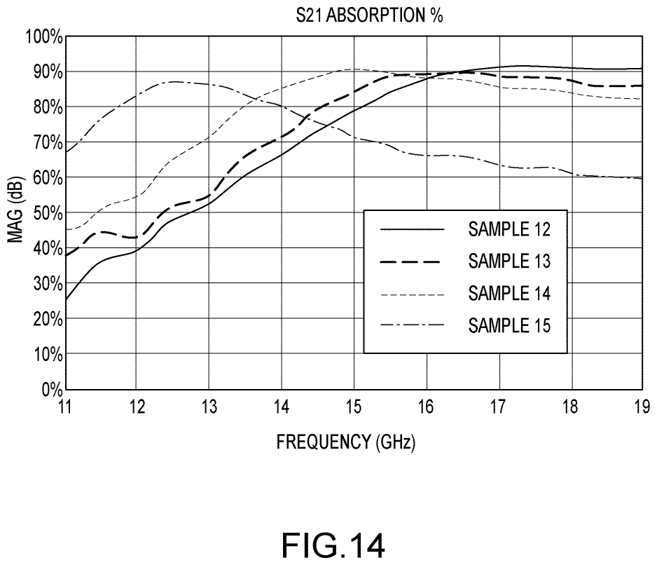

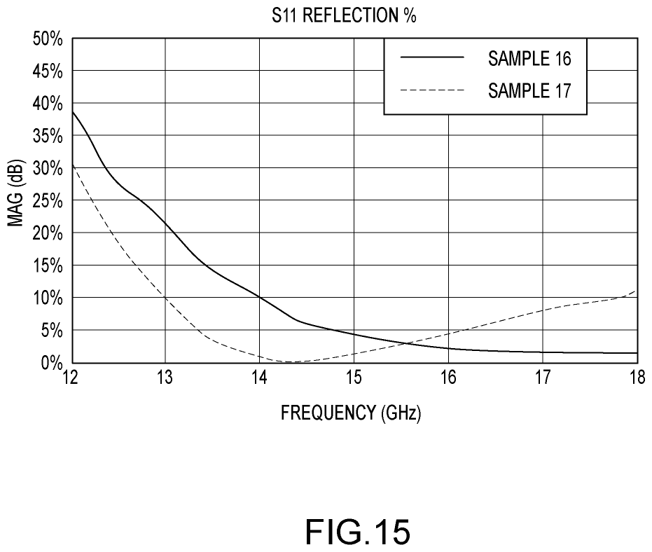

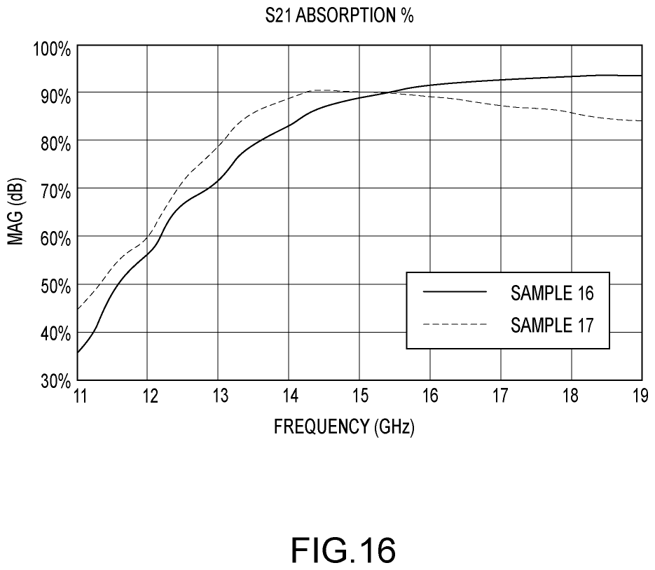

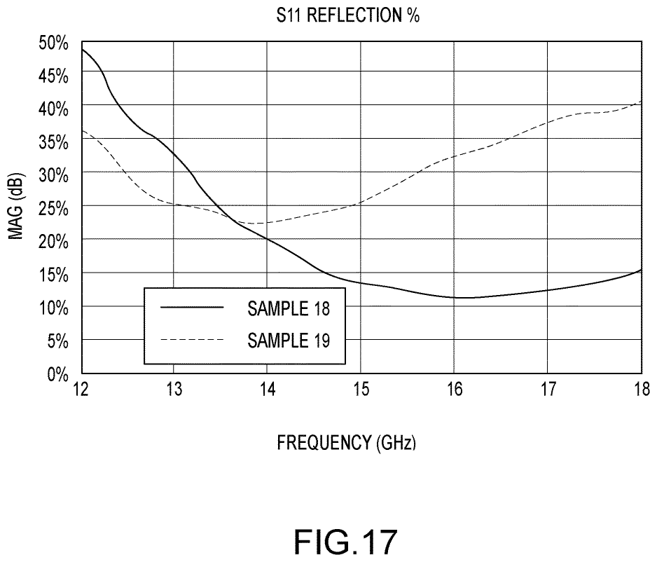

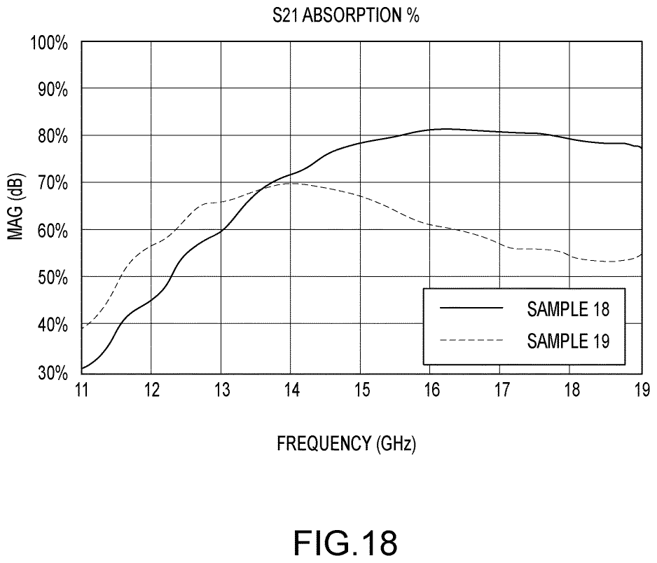

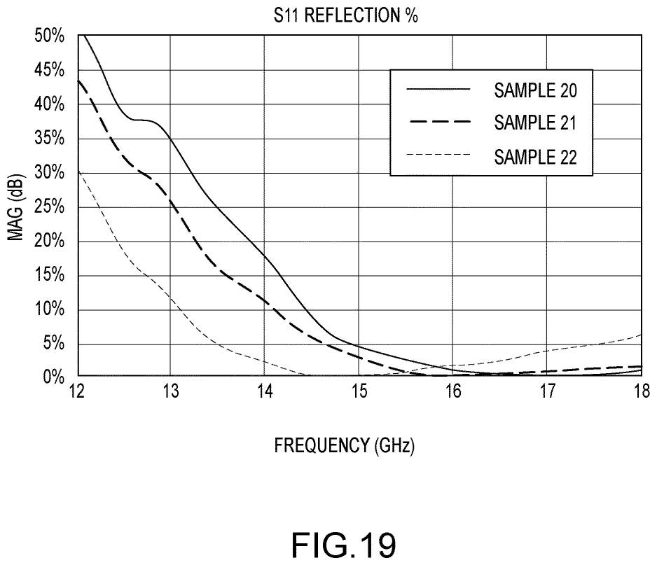

FIGS. 14-19 are more examples provided to demonstrate the effectiveness of the electromagnetic radiation attenuation apparatus of the present invention by using different filler systems including magnesia-based polymer composites with thicknesses of 1.75 mm and 2.0 mm (Samples 16-17); boron nitride-based polymer composites with thicknesses of 2.50 mm and 3.00 mm (Samples 18-19); and aluminum nitride-based polymer composites with thicknesses of 1.5 mm, 1.75 mm, and 2.0 mm (Samples 20-22) in the first layer and their reflection and absorption results.

1. An article for attenuating electromagnetic radiation, the article comprising:
a first layer having a first thickness defined between an incident surface and a transition surface thereof, a first polymer matrix, and a first filler in the first polymer matrix, wherein the first layer exhibits a first index of refraction to the electromagnetic radiation; and
a second layer disposed at the transition surface of the first layer, the second layer having a second polymer matrix and a second filler in the second polymer matrix suitable to absorb at least a portion of the electromagnetic radiation propagating into the second layer, wherein the second layer exhibits a second index of refraction to the electromagnetic radiation, and
wherein the first index of refraction is less than the second index of refraction by an amount that is effective to reduce emission reflection of the electromagnetic radiation incident upon the incident surface by at least 75%, wherein the incident electromagnetic radiation frequency is between 0.3-100 GHz.

2. The article as in claim 1 wherein the first thickness is between 0.1 mm and 20 mm.

3. The article as in claim 2 wherein the first thickness is between 0.5 and 4 mm.

4. The article as in claim 1 wherein the electromagnetic radiation exhibits a first wavelength in the first layer, and the first thickness is a product of the first wavelength and a destructive interference frequency factor, wherein the destructive interference frequency factor is between 0.2 and 0.3.

5. The article as in claim 4 wherein the destructive interference frequency factor is between 0.22 and 0.28.

6. The article as in claim 1 wherein the first index of refraction is within 25% of a square root of the second index of refraction.

7. The article as in claim 6 wherein the first index of refraction is within 10% of the square root of the second index of refraction.

8. The article as in claim 1 wherein the first index of refraction is between 1-7 for electromagnetic radiation frequencies of between 12-18 GHz.

9. The article as in claim 8 wherein the second index of refraction is between 5-16 for electromagnetic frequencies of between 12-18 GHz.

10. The article as in claim 1 wherein the first filler is selected from alumina, aluminum nitride, boron nitride, magnesia, alumina trihydrate, titanium dioxide, zinc oxide, aluminum hydroxide, zinc nitride, silicon carbide, silicon nitride, and combinations thereof, and the second filler is selected from silicon carbide, boron carbide, titanium dioxide, barium titanate, zinc oxide, aluminum powder, silver powder, magnetic metal powders, magnetic metal alloy powders, carbon fibers, graphite, carbon nanotubes, magnetic ceramics, iron, carbonyl ion, iron oxide, iron alloys, zinc alloys, and combinations thereof.

11. The article as in claim 1 wherein the first polymer matrix and the second polymer matrix are selected from silicone, polyethylene, polybutadiene, acrylic, epoxy, urethane, polysulfide, polyisobutylene, polyvinyl or polyolefin-based polymers, and combinations thereof.

12. The article as in claim 11 wherein the first polymer matrix employs a different polymer or polymer combination than the second polymer matrix.

13. The article as in claim 1 wherein the first polymer matrix comprises less than 10% by weight of the first layer.

14. An article for attenuating electromagnetic radiation, the article comprising:
a first layer having a first thickness defined between an incident surface and a transition surface thereof, a first polymer matrix, and a first filler in the first polymer matrix, wherein the electromagnetic radiation exhibits a first wavelength in the first layer, the first thickness being a product of the first wavelength and a destructive interference frequency factor, wherein the destructive interference frequency factor is between 0.2 and 0.3, and the first thickness being between 0.1 and 20 mm; and
a second layer having a first surface disposed at the transition surface of the first layer, the second layer having a second polymer matrix.

15. The article as in claim 14, including a second filler in the second polymer matrix suitable to absorb at least a portion of the electromagnetic radiation propagating into the second layer.

16. The article as in claim 15 wherein the second layer exhibits a second index of refraction, and the first layer exhibits a first index of refraction that is within 25% of a square root of the second index of refraction.

17. The article as in claim 14, including a reflector member disposed at a second surface of the second layer, the reflector member being effective to reflect electromagnetic radiation propagating through the second layer from the first layer.

18. An electronic apparatus, comprising:
an electronic device that operably emits electromagnetic radiation in a frequency range of between 0.3-100 GHz; and
the attenuation article as in claim 14 in proximity to the electronic device for attenuating the electromagnetic radiation.

19. The electronic apparatus as in claim 18 wherein at least the first layer of the attenuation article exhibits a Young's Modulus of less than 1 MPa at 25° C.

20. The electronic apparatus as in claim 19 wherein each of the first and second layers of the attenuation article exhibit a Young's Modulus of less than 1 MPa at 25° C.
